(19) United States
(12) Patent Application Publication
(10) Pub. No.: US 2026/0197973 A1
(43) Pub. Date: Jul. 9, 2026

(54) MULTI-LAYER TUBULAR WITH LEAK MITIGATION

(71) Applicant: Nvidia Corporation, Santa Clara, CA (US)

(72) Inventors: William Andrew Mecham, Elk Grove, CA (US); Ryan Albright, Beaverton, OR (US); William Ryan Weese, Portland, OR (US); Benjamin Goska, Portland, OR (US); Aaron Carkin, Hillsboro, OR (US); Michael Thompson, Wilsonville, OR (US); Jordan Levy, Portland, OR (US)

(21) Appl. No.: 19/013,267

(22) Filed: Jan. 8, 2025

(51) Int. Cl. H05K 7/20; F16L 11/10; F16L 55/16

(52) U.S. Cl. CPC H05K 7/20327; F16L 11/10; F16L 55/1616

(57) ABSTRACT

Systems and methods are directed toward multi-layer tubular arrangements that include a flow restrictive material between a first layer and a second layer. The first layer may be associated with a flow bore and may be surrounded, at least partially, by a flow restrictive material. The flow restrictive material may also be surrounding by a second layer. If an opening or hole forms in either the first or second layers, the flow restrictive material may block fluid ingress/egress to maintain operation of the multi-layer tubular until maintenance or repairs can be scheduled.

### TECHNICAL FIELD

At least one embodiment pertains to liquid cooling systems. More specifically, at least one embodiment pertains to one or more tubulars used to transport cooling liquid.

### BACKGROUND

Data centers may contain a number of compute units, which may be arranged in a variety of configurations, such as rack-mounted systems that include rows of racks that include a number of different sets of compute units. Compute units may be referred to as heat generating units within a data center and are often configured to run within a given temperature range. More compute-intense operations may generate more heat, which may be beyond the capabilities of air only cooling systems. As a result, data centers may incorporate liquid cooling systems, which may include cooling at a rack-level or at a chip-level, among other options. Liquid may be provided to a variety of different cooling configurations using one or more tubulars. In operation, leaks may occur at different parts of the cooling system, for example due to damage to tubulars or connections, among other reasons. Because compute units are sensitive electronic devices, early leak detection and mitigation may be used to quickly identify and isolate leaks to prevent damage.

### BRIEF DESCRIPTION OF THE DRAWINGS

Various embodiments in accordance with the present disclosure will be described with reference to the drawings, in which:

FIG. 1 illustrates an example data center cooling system, according to at least one embodiment;

FIG. 2A illustrates an example data center cooling system, according to at least one embodiment;

FIG. 2B illustrates rack-level features associated with a data center cooling system, according to at least one embodiment;

FIG. 2C illustrates rack-level features associated with a data center cooling system, according to at least one embodiment;

FIG. 3A illustrates an example front cross-sectional view of an embodiment of a multi-layer tubular, according to at least one embodiment;

FIG. 3B illustrates an example side cross-sectional view of an embodiment of a multi-layer tubular, according to at least one embodiment;

FIG. 3C illustrates an example front cross-sectional view of an embodiment of a multi-layer tubular, according to at least one embodiment;

FIG. 3D illustrates an example side cross-sectional view of an embodiment of a multi-layer tubular, according to at least one embodiment;

FIG. 3E illustrates an example schematic representation of a multi-layer tubular associated with a cooling fluid system, according to at least one embodiment;

FIG. 4A illustrates an example sectional front cross-sectional view of an embodiment of a multi-layer tubular, according to at least one embodiment;

FIG. 4B illustrates an example sectional front cross-sectional view of an embodiment of a multi-layer tubular, according to at least one embodiment;

FIG. 4C illustrates an example sectional front cross-sectional view of an embodiment of a multi-layer tubular, according to at least one embodiment;

FIG. 4D illustrates an example sectional front cross-sectional view of an embodiment of a multi-layer tubular, according to at least one embodiment;

FIG. 4E illustrates an example sectional front cross-sectional view of an embodiment of a multi-layer tubular, according to at least one embodiment;

FIG. 4F illustrates an example sectional front cross-sectional view of an embodiment of a multi-layer tubular, according to at least one embodiment;

FIG. 5A illustrates an example process for forming a multi-layer tubular, according to at least one embodiment;

FIG. 5B illustrates an example process for detecting a leak associated with a multi-layer tubular, according to at least one embodiment;

FIG. 6 illustrates components of a distributed system that can be utilized to update or perform inferencing using a machine learning model, according to at least one embodiment;

FIG. 7 illustrates an example data center system, according to at least one embodiment;

FIG. 8 illustrates a computer system, according to at least one embodiment;

FIG. 9 illustrates a computer system, according to at least one embodiment; and

FIG. 10 illustrates at least portions of a graphics processor, according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various embodiments are directed toward a leak mitigation system that includes a multi-layer cooling fluid transport tube (e.g., tubular) that includes a coagulant or hydrophobic material between layers of tubing. In at least one embodiment, the system includes at least two different concentric layers with an annular void space between the layers. The void space is filled, at least partially, by a flow restrictive material (e.g., a coagulant material, a hydrophobic material, etc.) that may be used to plug and/or otherwise address leaks within the tubing. If the leak is formed at the inner layer, as the cooling fluid flows into the annulus, the coagulant may block further movement of the cooling fluid toward the outer layer. If the leak is formed at the outer layer, the coagulant may be pushed or otherwise flow toward the leak point in the outer layer, blocking flow out of the tubular. Various embodiments may include multiple layers, segmented or sectioned layers, or combinations thereof. Additionally, different embodiments may use different material to form the inner and outer layers of the tubing. Accordingly, embodiments may be used to address “pinhole” leaks so that systems and can be identified as having small leaks and then maintenance can be scheduled to address the leaks instead of suddenly shutting down different systems.

One or more embodiments are directed toward a cooling fluid transport tubular including a material positioned between two layers of the tubular. In at least one embodiment, the material may be a hydrophobic material, a coagulating material, and/or combinations thereof. The cooling fluid transport tubular may include a first annular layer forming a flow bore for the tubular and a second annular layer positioned radially outward from and coaxial with the first annular layer. In at least one embodiment, the multi-layer tubular may include a flow restrictive material positioned within an annular space between the first annular layer and the second annular layer. The flow restrictive material may be used to restrict flow of a cooling fluid, within the flow bore, responsive to at least one of a first opening in the first annular layer or a second opening in the second annular layer. That is, the flow restrictive material may be used to block flow into the multi-layer tubular and/or to block flow out of the multi-layer tubular. In at least one embodiment, the flow restrictive material is a hydrophobic material. The hydrophobic material may refer to a material that is insoluble in water or other polar solvents and may further be described as being water resistant or water repellant. One or more embodiments may include hydrophobic materials that include, as non-limiting examples, at least one of an acrylic, an epoxy, a polyethylene, a polystyrene, a polyvinylchloride, a polytetrafluorethylene, a polydimethylsiloxane, a polyester, or a polyurethane. Additionally, in one or more embodiments, the flow restrictive material may be a coagulant that, when mixed with the cooling fluid, will cause at least a portion of the cooling fluid to become hydrophobic. Furthermore, one or more embodiments may include one or more different types of flow restrictive material. In the example of the flow restrictive material being a coagulant, the flow restrictive material, when mixed with the cooling fluid, may cause a mixture of the cooling fluid and the flow restrictive material to clog the second opening. Systems and methods may also include configurations wherein the first annular layer is formed from a first material and the second annular layer is formed from a second material. For example, first annular layer may be a flexible polymer and the second annular layer may be a puncture resistant material. As a result, the multi-layer tubular may be formed from one or more materials to accommodate intended uses, such as having the puncture resistant material on an external portion that will be subject to contact by other materials and components. In at least one embodiment, the puncture resistant material may include at least one of a carbon fiber weave, acrylonitrile butadiene styrene (ABS), or a metallic braiding.

Embodiments of the present disclosure may also be directed toward one or more configurations in which a coagulant material is arranged within an annular space between layers of a tubular so that, when wetted by a cooling fluid, the coagulant material will plug one or more leaks. As an example, a multi-layer tubular may include an inner layer proximate to and/or forming a flow bore for a cooling fluid. There may be an annular space around the inner layer, separated from the flow bore by the inner layer. In at least one embodiment, an outer layer is proximate the annular space and separated from the flow bore by both the annular space and the inner layer. As a result, the inner and outer layers may be described as being coaxial, with the outer layer positioned radially outward from the inner layer. In one or more embodiments, the annular space includes a coagulant material that, upon contacting the cooling fluid responsive to an inner leak path in the inner layer, causes the cooling fluid to become a hydrophobic material, and upon becoming a hydrophobic material, clogs an outer leak path in the outer layer. In at least one embodiment, the inner layer is formed from a first material and the outer layer is formed from a second material. For example, the inner layer may be a flexible polymer and the outer layer may be a puncture resistant material, such as at least one of a carbon fiber weave, ABS, or a metallic braiding. In certain embodiments, the multi-layer tubular may be segmented into a plurality of segments. The plurality of segments may include a first segment proximate a first connection, a second segment proximate a second connection, and a third segment between the first segment and the second segment. In at least one embodiment, the coagulant material may be positioned within the first segment and the second segment and not within the third segment. Furthermore, one or more embodiments may be associated with a detection system that generates a signal responsive to detecting at least one of the inner leak path or the outer leak path based, at least in part, on the clog at the outer layer. The multi-layer tubular may include a variety of different dimensional configurations. For example, a first radial thickness of the annular space may be greater than a second radial thickness of the inner layer and a third radial thickness of the outer layer. In at least one embodiment, a first radial thickness of the annular space is less than at least one of a second radial thickness of the inner layer or a second radial thickness of the outer layer. Systems and methods may include a coagulant material that is formed by at least one of aluminum sulfate, aluminum chloride, sodium aluminate, ferric sulfate, ferrous sulfate, ferric chloride, or ferric chloride sulfate.

One or more embodiments of the present disclosure are directed toward a multi-layer tubular that may include one or more materials that may be used to turn a fluid into a hydrophobic fluid and/or to absorb a fluid. For example, a multi-layer cooling fluid hose may include at least a first layer and a second layer radially separated by an annular space. The annular space may be filled, at least partially, with a flow restrictive material to cause a liquid that enters the annular space, through at least one of a first leak path formed in the first layer or a second leak path formed in the second layer, to become hydrophobic or to absorb at least a portion of the liquid. In one or more embodiments, the multi-layer cooling fluid hose forms a portion of a liquid cooling loop associated with a server product to direct a cooling fluid, flowing through a bore of the multi-layer cooling fluid hose, toward heat producing units to absorb and remove heat from the heat producing units. The flow-restrictive material may be selected based, at least in part, on one or more thermal properties.

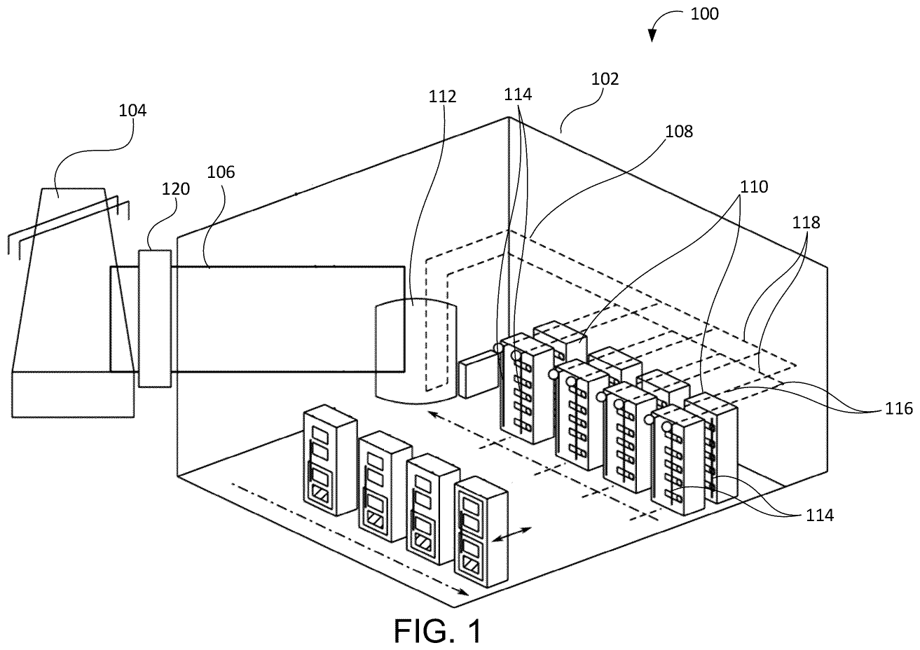

In at least one embodiment, a data center 100 can be utilized as illustrated in FIG. 1, which has a cooling system. In at least one embodiment, numerous specific details are set forth to provide a thorough understanding, but concepts herein may be practiced without one or more of these specific details. In at least one embodiment, data center cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a data center. In at least one embodiment, heat generated from these components, servers, and racks are cumulatively referred to as a heat feature or a cooling requirement as cooling requirement must address a heat feature entirely.

In at least one embodiment, a data center liquid cooling system is disclosed. In at least one embodiment, this data center cooling system addresses heat features in associated computing or data center devices, such as in graphics processing units (GPUs), in switches, in dual inline memory modules (DIMMs), in data processing units (DPUs), in quantum processing units (QPUs), and in data or central processing units (CPUs). In at least one embodiment, these components may be referred to herein as high heat density computing components. Furthermore, in at least one embodiment, an associated computing or data center device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature. QPUs may be configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

In at least one embodiment, a liquid-cooled data center may have a stand-alone or a rack-mount chemistry sensor system as part of one or more sensors of a monitoring system. In at least one embodiment, such one or more sensors are able to perform continuous testing or monitoring of working fluids, such as coolants that are either primary coolant, secondary coolant, or local coolant. In at least one embodiment, secondary coolant may be cooled by a primary coolant, whereas local coolant may be independently cooled or may also be cooled by a primary coolant. In at least one embodiment, upon a change in chemistry determined by at least one processor, additives may be provided for a coolant.

In at least one embodiment, local or other coolant readily available in a preloaded system may be mixed with secondary coolant as an additive. In at least one embodiment, a reservoir of available additives may be provided where such local coolant, primary coolant, secondary coolant, and additives are dispensed using one or more flow controllers. In at least one embodiment, additives may include inhibitors, biocide controls, and other such chemicals used to balance a chemistry of a working fluid, such as of primary coolant, secondary coolant, or local coolant (in itself). In at least one embodiment, such balancing enables optimized chemistry of a coolant within plumbing associated with a data center cooling system. In at least one embodiment, continuous monitoring and chemistry balancing enables a highly efficient operation in a data center cooling system. In at least one embodiment, such plumbing may include cooling distribution units (CDUs), cooling manifolds (or simply referred to as manifolds), tubes, pumps, joints, and cold plates. In at least one embodiment, such working fluid may be used to remove heat from an associated computing device, such as a GPU, a CPU, a switch, or from other components of a server.

In at least one embodiment, a data center 100 can be utilized as illustrated in FIG. 1, which has a cooling system subject to improvements described herein. In at least one embodiment, a data center 100 may be one or more rooms 102 having racks 110 and auxiliary equipment to house one or more servers on one or more server trays. In at least one embodiment, a data center 100 is supported by a cooling tower 104 located external to a data center 100. In at least one embodiment, a cooling tower 104 dissipates heat from within a data center 100 by acting on a primary cooling loop 106. In at least one embodiment, a cooling distribution unit (CDU) 112 is used between a primary cooling loop 106 and a second or secondary cooling loop 108 to enable absorption of heat from a second or secondary cooling loop 108 to a primary cooling loop 106. In at least one embodiment, a secondary cooling loop 108 can access various plumbing into a server tray as required, in an aspect. In at least one embodiment, cooling loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided cooling loop 106, 108. In at least one embodiment, one or more coolant pumps may be used to maintain pressure differences within cooling loops 106, 108 to enable movement of coolant according to temperature sensors in various locations, including in a room, in one or more racks 110, and/or in server boxes or server trays within one or more racks 110.

In at least one embodiment, coolant in a primary cooling loop 106 and in a secondary cooling loop 108 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 110. In at least one embodiment, a CDU 112 is capable of sophisticated control of coolants, independently or concurrently, within provided cooling loops 106, 108. In at least one embodiment, a CDU may be adapted to control flow rate of coolant so that coolant is appropriately distributed to absorbed heat generated within associated racks 110. In at least one embodiment, more flexible coolant tubing 114 is provided from a secondary cooling loop 108 to enter each server tray to provide coolant to electrical and/or computing components therein.

In at least one embodiment, row manifold tubing 118 that forms part of a secondary cooling loop 108 may be referred to as room manifolds. Separately, in at least one embodiment, additional tubing 116 may extend from row manifold tubing 118 and may also be part of a secondary cooling loop 108 but may be referred to as row manifolds. In at least one embodiment, flexible coolant tubing 114 enters racks as part of a secondary cooling loop 108 but may be referred to as rack cooling manifold within one or more racks. In at least one embodiment, additional tubing 116 extend to all racks along a row in a data center 100. In at least one embodiment, plumbing of a secondary cooling loop 108, including coolant row manifold tubing 118, additional tubing 116, and flexible coolant tubing 114 may be improved by at least one embodiment herein. In at least one embodiment, a chiller 120 may be provided in a primary cooling loop within data center 100 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 110 may be transferred to a coolant exiting one or more racks 110 via flexible tubing such as flexible coolant tubing 114 of a second cooling loop 108. In at least one embodiment, second coolant (in a secondary cooling loop 108) from a CDU 112, for cooling provided racks 110, moves towards one or more racks 110 via provided tubing. In at least one embodiment, second coolant from a CDU 112 passes from one side of a room manifold having row manifold tubing 118, to one side of a rack 110 via additional tubing 116, and through one side of a server tray via different flexible coolant tubing 114. In at least one embodiment, spent or returned second coolant (or exiting second coolant carrying heat from computing components) exits out of another side of a server tray (such as enter left side of a rack and exit right side of a rack for a server tray after looping through a server tray or through components on a server tray). In at least one embodiment, spent second coolant that exits a server tray or a rack 110 comes out of different side (such as exiting side) of flexible coolant tubing 114 and moves to a parallel, but also exiting side of additional tubing 116. In at least one embodiment, from additional tubing 116, spent second coolant moves in a parallel portion of a room manifold tubing 118 and is going in an opposite direction than incoming second coolant (which may also be renewed second coolant), and towards a CDU 112.

In at least one embodiment, spent second coolant exchanges its heat with a primary coolant in a primary cooling loop 106 via a CDU 112. In at least one embodiment, spent second coolant may be renewed (such as relatively cooled when compared to a temperature at a spent second coolant stage) and ready to be cycled back to through a second cooling loop 108 to one or more computing components. In at least one embodiment, various flow and temperature control features in a CDU 112 enable control of heat exchanged from spent second coolant or flow of second coolant in and out of a CDU 112. In at least one embodiment, a CDU 112 may be also able to control a flow of primary coolant in primary cooling loop 106.

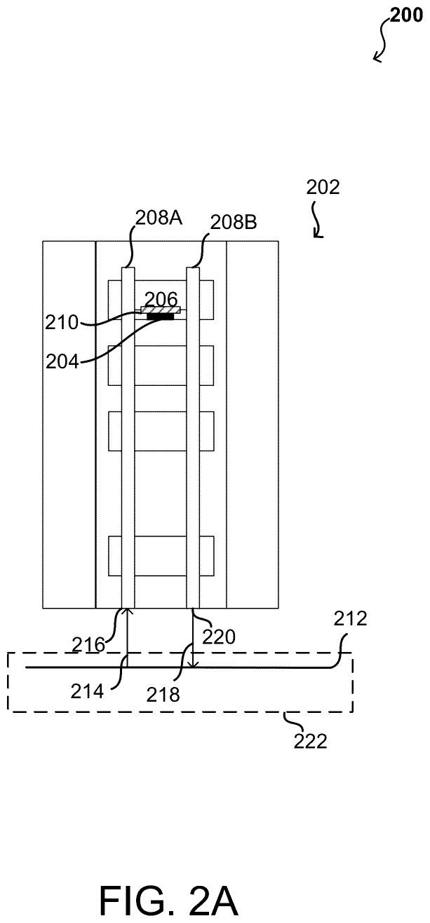

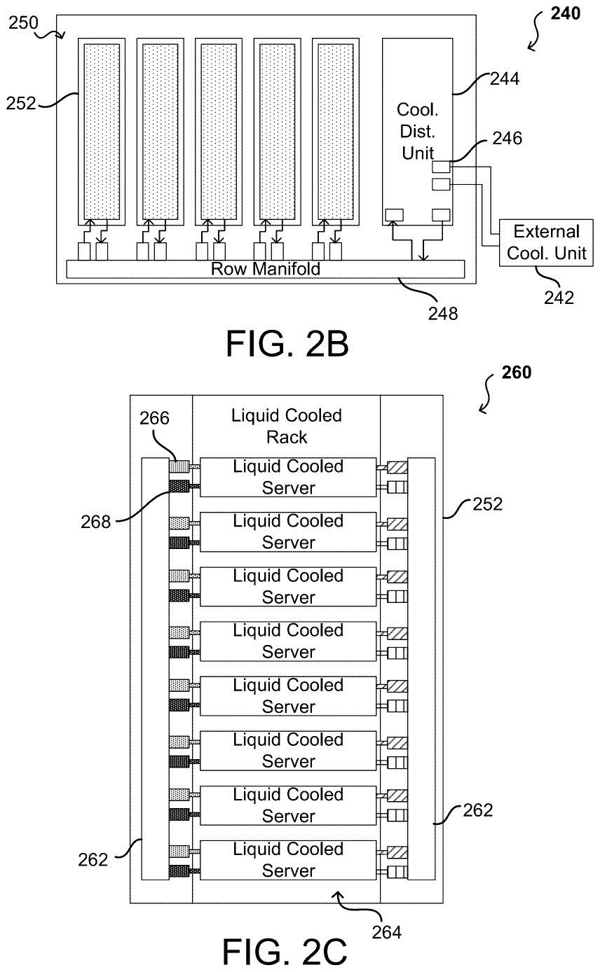

FIG. 2A illustrates an example environment 200 that may be used with embodiments of the present disclosure to provide cooling fluid to one or more computing devices. In this example, a rack 202 is used to house a number of computing devices 204 (e.g., servers, processing units, etc.) in a stacked configuration. The configuration of FIG. 2A may be referred to as showing “rack-level features” for cooling one or more computing devices 204, but embodiments of the present disclosure are not limited to only rack-level cooling and may be expanded to other cooling configurations and arrangements.

The illustrated rack 202 includes a number of shelves 206 that may hold one or more computing devices 204. Each of these shelves 206, and/or the computing devices 204 associated with the shelves 206, may be associated with manifolds 208, which may include an inlet manifold 208A (e.g., a supply manifold) and an outlet manifold 208B (e.g., a return manifold), to provide a cooling fluid to dissipate heat away from the one or more computing devices 204 and then to carry heated fluid away from the one or more computing devices 204. In this example, the manifolds 208 may be coupled to one or more heat plates 210 associated with the one or more computing devices 204, for example via tubing or the like. As discussed herein, the tubing may include plastic tubing, metallic tubing, composite tubing, and/or combinations thereof.

The shelves 206 may also include a variety of different sensors, which may be mounted within the shelf. For example, fluid detectors, such as ribbon detectors, may be positioned within the shelves 206 to detect leaks associated with a cooling fluid system 222. However, these sensors often need a threshold amount of liquid prior to obtaining a signal indicative of a leak. Often, by the time the leak is detected, damage is significant and/or may lead to a sudden preventative action, instead of proactively identifying leaks and then scheduling maintenance. Embodiments of the present disclosure may address and overcome this problem may detecting leaks sooner and at smaller quantities of leaked fluid.

While the illustrated example includes a single inlet manifold 208A and a single outlet manifold 208B, various embodiments may include more manifolds 208 and the manifolds may be arranged at different locations. For example, the manifolds 208 may be arranged at sides of the rack 202 to provide improved access to the interior of the rack, such as the shelves 206. Additionally, in at least one embodiment, the manifolds 208A, 208B may be positioned on opposite sides of the rack 202. Furthermore, embodiments may include multiple manifolds 208, with particular manifolds being used to direct fluid to/from particular shelves 206. Accordingly, a variety of configurations for cooling manifolds may be used within the scope of the present disclosure.

The manifolds 208 are shown coupled to a row manifold 212, which may be part of a secondary cooling loop. The row manifold 212 may include both an “inlet” line that carries cool fluid toward the shelves 206 and an “outlet” line that carries heated fluid away from the shelves 206. The row manifold 212 may include a connection 214 to a source inlet 216 of the manifold 208A and a connection 218 to a source outlet 220. The source inlet 216 may carry the cooled fluid along a length of the manifold to one or more outlets that may direct the cooled fluid toward the heat plates 210. The heat plates 210 may then include different connections to inlets of the manifold 208B that may direct heated fluid to the source outlet 220 to return to the row manifold 212 so that heated fluid may be cooled and then reused. As discussed herein, the row manifold 212 may be part of one or more cooling fluid systems 222, which may include components discussed, for example, in FIG. 1.

FIG. 2B illustrates a system 240 that may be used with embodiments of the present disclosure. The illustrated system 240 may include various features discussed with reference to FIG. 2A and herein, such an external cooling unit 242, such as a cooling tower, which may be part of an overall data center cooling system. This example illustrates the external cooling unit 242 coupled to a cooling distribution unit 244, which may be for a data center as a whole, or in certain embodiments, may be a localized cooling distribution unit at a rack or row level, among other options. The illustrated cooling distribution unit 244 may include a control board 246 to receive data from a variety of sensors associated with the cooling system. For example, the one or more sensors may provide coolant flow rate data, cooling pressure data, status of auxiliary systems, and/or the like.

The illustrated embodiment includes a row manifold 248 that sends/receives cooling fluid to/from the cooling distribution unit 244. The row manifold 248 also distributes and receives cooling fluid from a row 250 of racks 252, which in this example are liquid cooled racks. In at least one embodiment, there can be different levels of flow into, and out of, different liquid cooled racks. Additionally, there may also be different flows into individual servers in a rack. As discussed herein, systems and methods of the present disclosure may be used to form one or more portions of the row manifold 248 and/or may be used as part of a rack-specific manifold, as discussed herein.

FIG. 2C illustrates a system 260 that may be used with embodiments of the present disclosure. This example system includes the rack 252 with rack-level manifolds 262. As shown, the rack 252 includes a number of liquid cooled servers 264 or other such devices. In at least one embodiment, the rack-level manifold 262 provides a flow of liquid into each liquid cooled server 264 through an inlet valve 266, and return liquid with heat removed from that liquid cooled server 264 through an outlet valve 268. In at least one embodiment, sensors can capture information about temperature, fluid flow, or other such aspects of a computing environment internal and/or external to the rack 252, including internal and/or external to any individual liquid cooled servers 264 located therein. Fluid associated with the rack-level manifold 262 may be used to remove an amount of heat from liquid cooled servers 264, but due to factors such as varying load and external temperature fluctuations, temperatures at various locations may change, and may reach or exceed temperature limits at which these devices can continue to operate correctly. In at least one embodiment, an attempt can be made to ensure that temperatures at specific locations remain below an acceptable limit, where those locations may relate to junction temperatures or core temperatures for a processor (e.g., a CPU or GPU), memory module, or power supply. The liquid generally includes water, water solutions (e.g., propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g., a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2,3,3,3-tetrafluoropropene, 1,1,1,2-tetrafluoroethane and water.

In at least one embodiment, fluid quality is monitored and controlled at a rack level using one or more assemblies or sensors, for example inline flow sensors that can be associated with the rack-level manifold 262 as a whole and/or for individual liquid cooled servers 264. Different racks and servers may have different flow characteristics, such as different diameter flow channels in direct-to-chip cooling boards, and as a result, different cooling configurations, different manifold sizes, and/or different manifold properties may be used.

Systems and methods of the present disclosure may provide a mechanism for mitigation of leaks in a liquid cooled loop via a multi-layer tubular (e.g., tube, hose, etc.) with one or more layers of flow-resistant material between at least two layers of the multi-layer tubular. One of the challenges of liquid cooled systems are potential leaks, which may be more critical as density of various computing systems increases. Currently, single walled tubulars are used, which are vulnerable to puncture or wear-induced weaknesses. Embodiments of the present disclosure address the problems with single walled tubulars by introducing a multi-layer tubular, such as a double walled tubular as one non-limiting example, with a layer of flow-resistant material between at least some of the walls. As one non-limiting example, a coagulant material may be positioned within layers of a double walled tubular. An outer layer may be formed from a tough, puncture resistant material (e.g., carbon fiber weave, steel braiding, ABS, etc.) that can add extra production against external leak factors. Between a least one outer layer and at least one inner layer, systems and methods may integrate one or more layers of coagulant material that will cause a liquid to either become hydrophobic (e.g. via silicon dioxide dust) to help clog a leak point and/or to act as an absorbent material to minimize potential damage until a remedy can be applied increasing the system safety. In example embodiments, the silicon dioxide dust can help prevent moisture from penetrating through any potential leaks in the tube. When a liquid contacts the coagulant or silicon dioxide dust, it may form beads on the surface rather than spreading out and seeping through gaps or cracks. This can provide an additional barrier against leaks by minimizing the likelihood of water infiltration. As a result, potential damage to conductive materials associated with compute units may be reduced. Furthermore, if there is a leak in the tube, the movement of fluid could disturb the coagulant or silicon dioxide dust, causing it to migrate toward the leak site. The fine particles may then accumulate at the opening, effectively clogging it. Furthermore, the coagulant or silicon dioxide dust may have a high surface area and can absorb some liquids due to its porous nature. If a leak occurs, the coagulant or silicon dioxide dust might absorb some of the leaking fluid.

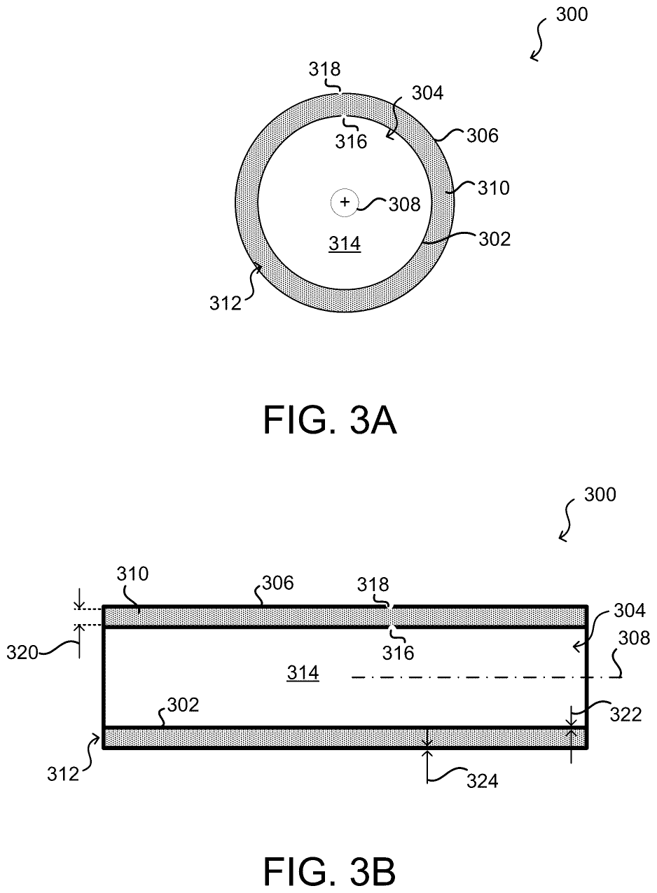

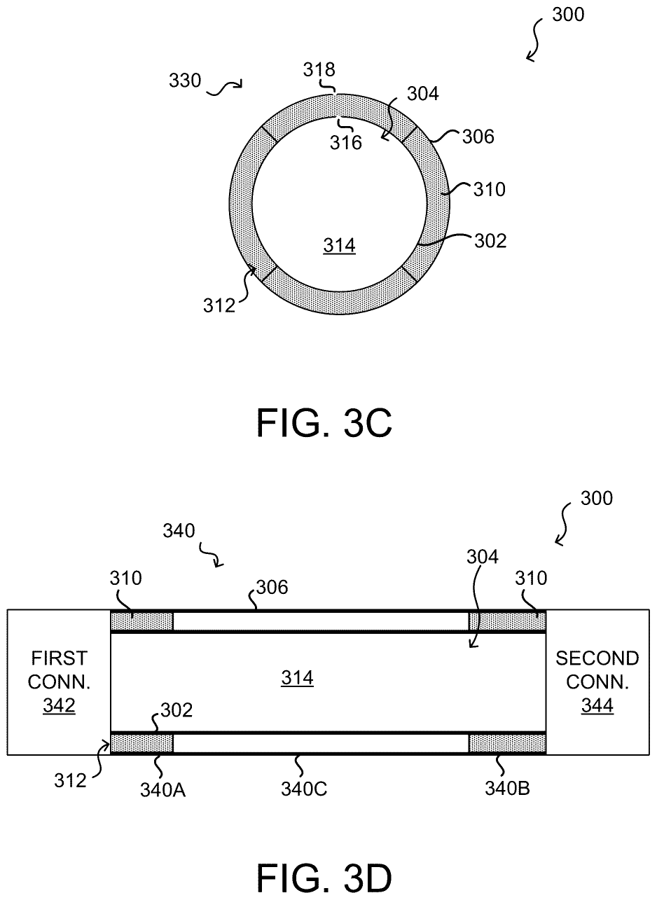

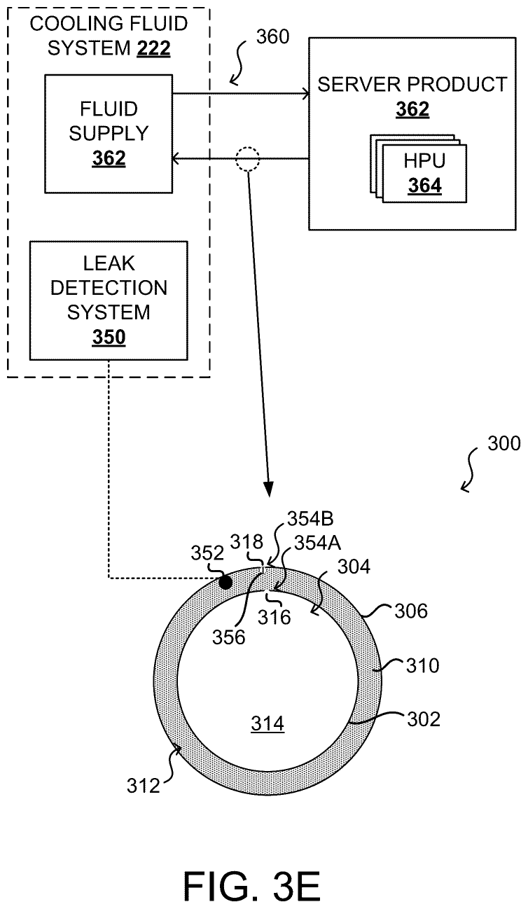

FIG. 3A illustrates a cross-sectional front view of an embodiment of a multi-layer tubular 300, which may also be referred to as a tube, a hose, a cooling fluid transport tubular, or the like. This example includes a first layer 302 (e.g., a first annular layer, an inner layer) forming a flow bore 304 for the multi-layer tubular 300. Additionally, a second layer 306 (e.g., a second annular layer, an outer layer) is illustrated as being positioned radially outward from and coaxial with the first layer 302. That is, an axis 308 is shared by both the first layer 302 and the second layer 306.

In at least one embodiment, the multi-layer tubular 300 may include a flow restrictive material 310 positioned within an annular space 312. The annular space 312 corresponds to a space or void between the first annular layer 302 and the second annular layer 306. As shown, in this example, the first annular layer 302 is separated from the second annular layer 306 by the annular space 312 and/or the flow restrictive material 310 within the annular space 312. In at least one embodiment, the flow restrictive material may be used to restrict flow of a cooling fluid 314, within the flow bore 304, responsive to at least one of a first opening 316 in the first annular layer 302 or a second opening 318 in the second annular layer 306. The first opening 316 and/or the second opening 318 may refer to a puncture or a break in a continuous annular body of the first annular layer 302 and/or the second annular layer 306. As discussed herein, the flow restrictive material 310 may not entirely or fully fill the annular space 312 and there may be gaps, spaces, openings, and/or the like, which may improve flexibility of the multi-layer tubular 300.

In operation, the flow restrictive material 310 may be used to block flow into the annular space 312 of the multi-layer tubular 300 and/or to block flow out of the multi-layer tubular 300, for example from the annular space 312 through the second annular layer 306. As one example, the first opening 316 may cause the cooling fluid 314 within the flow bore 304 to try and flow into the annular space 312. The flow restrictive material 310 would be configured to block the flow into the annular space 312, for example by resisting the flow, forming a clot to plug the first opening 316, and/or absorbing the cooling fluid 314. As another example, the second opening 318 may cause an external liquid to flow into the annular space 312. The flow restrictive material 310 would be configured to block the flow into the annular space 312, for example by resisting the flow, forming a clot to plug the second opening 318, and/or absorbing the external liquid. As another example, the first and second openings 316 and 318 may cause the cooling fluid 314 within the flow bore 304 to try and flow into the annular space 312 and then out of the multi-layer tubular 300 from the annular space 312. The flow restrictive material 310 would be configured to block the flow into the annular space 312, for example by resisting the flow, forming a clot to plug the first opening 316, and/or absorbing the cooling fluid 314. Additionally, the flow restrictive material 310 would be configured to block the flow out of the annular space 312, for example by forming a clot to plug the second opening 318 and/or absorbing the cooling fluid 314. In at least one embodiment, the flow restrictive material is a hydrophobic material, which may be used to describe a material that is insoluble in water or other polar solvents. Hydrophobic materials may also refer to materials that are water resistant or repel water. One or more embodiments may include hydrophobic materials that include, as non-limiting examples, at least one of an acrylic, an epoxy, a polyethylene, a polystyrene, a polyvinylchloride, a polytetrafluorethylene, a polydimethylsiloxane, a polyester, or a polyurethane.

In at least one embodiment, the flow restrictive material 310 may be a coagulant that, when mixed with the cooling fluid 314, will cause at least a portion of the cooling fluid 314 to become hydrophobic. Furthermore, one or more embodiments may include one or more different types of flow restrictive material 310. In the example of the flow restrictive material 310 being a coagulant, the flow restrictive material 310, when mixed with the cooling fluid 314, may cause a mixture of the cooling fluid 314 and the flow restrictive material 310 to clog the second opening 318. Embodiments may also include combinations of flow restrictive materials 310. For example, an absorbent layer may be positioned proximate the first annular layer 302 and then a coagulant material may be positioned proximate the second annular layer 306. As a result, if cooling fluid 314 were to enter the annular space 312 via the first opening 316, the first layer of flow restrictive material 310 could begin to absorb the cooling fluid 314 and then, if the first layer of flow restrictive material 310 were to saturate, the second layer of flow restrictive material 310 would clog the second opening 318 to block flow out of the multi-layer tubular 300.

Systems and methods may also include configurations wherein the first annular layer 302 is formed from a first material and the second annular layer 306 is formed from a second material. For example, first annular layer 302 may be a flexible polymer and the second annular layer 306 may be a puncture resistant material. As a result, the multi-layer tubular 300 may be formed from one or more materials to accommodate intended uses, such as having the puncture resistant material on an external portion that will be subject to contact by other materials and components. In at least one embodiment, the puncture resistant material may include at least one of a carbon fiber weave, ABS, or a metallic braiding.

FIG. 3B illustrates a side cross-sectional view of an embodiment of the multi-layer tubular 300 that may be used with embodiments of the present disclosure. In the illustrated example, the flow restrictive material 310 may correspond to a coagulant material, which is illustrated within the annular space 312 between the first and second annular layers 302, 306 of the multi-layer tubular 300 so that, when wetted by the cooling fluid 314, the coagulant material (as the flow restrictive material 310) will plug one or more leaks, such as leaks associated with the first opening 316 and/or the second opening 318.

In at least one embodiment, the multi-layer tubular 300 may include the first annular layer 302, also referred to as a first annular layer or a first layer, proximate to and/or forming the flow bore 304 for the cooling fluid 314. As discussed herein, the cooling fluid 314 may include a liquid, gas, solid, and/or combinations thereof. The example further illustrates the annular space 312 around the first annular layer 302, separated from the flow bore 304 by the inner layer 302. For example, the first annular layer 302 may have a continuous perimeter that contains or otherwise forms the flow bore 304. In at least one embodiment, the second annular layer 306, also referred to as a second annular layer or a second layer, is proximate the annular space 312 and separated from the flow bore 304 by both the annular space 312 and the first annular layer 302. As a result, the first and second annular 302, 306 may be described as being coaxial with respect to the axis 308, with the second annular layer 306 positioned radially outward from the first annular layer 302. In one or more embodiments, the annular space 312 includes the flow restrictive material 310, which in this example may be a coagulant material, that, upon contacting the cooling fluid 314 responsive to an inner leak path 354A, also referred to as a first leak path, a first opening, or an inner opening, in the first annular layer 302, causes the cooling fluid 314 to become a hydrophobic material. Upon becoming a hydrophobic material, the combination of the cooling fluid 314 and the coagulant material may clog the outer leak path 354B, also referred to as a second leak path, a second opening, or an outer opening, in the second annular layer 306. Systems and methods may include a coagulant material that is formed by at least one of aluminum sulfate, aluminum chloride, sodium aluminate, ferric sulfate, ferrous sulfate, ferric chloride, or ferric chloride sulfate. In at least one embodiment, the first annular layer 302 is formed from a first material and the second annular layer 306 is formed from a second material. For example, the first annular layer 302 may be a flexible polymer and the second annular layer 306 may be a puncture resistant material, such as at least one of a carbon fiber weave, ABS, or a metallic braiding.

The multi-layer tubular 300 may include a variety of different dimensional configurations. For example, a first radial thickness 320 of the annular space 312 (e.g., a first thickness, an annular space thickness, etc.) may be greater than a second radial thickness 322 of the first annular layer 302 (e.g., a second thickness, a first layer thickness, an inner layer thickness, etc.) and a second radial thickness 324 of the second annular layer 306 (e.g., a third thickness, a second layer thickness, an outer layer thickness, etc.). In at least one embodiment, the first radial thickness 320 of the annular space 312 may be less than at least one of the second radial thickness 322 of the first annular layer 302 or the second radial thickness 324 of the second annular layer 306.

FIG. 3C illustrates an example front cross-sectional view of an embodiment of the multi-layer tubular 300 including a plurality of segments 330. In this example, the segments 330 are illustrated radially around the flow bore 304. While the example includes four segments 330, it should be appreciated that various embodiments may include more or fewer segments. Furthermore, respective segment circumferential extents may not be equal. For example, a first segment may extend for approximately 90 degrees while a second segment extends for approximately 70 degrees, and so forth. Embodiments may particularly select different segment lengths and/or positions based on desired operating conditions, among other options.

FIG. 3D illustrates an example side cross-sectional view of an embodiment of the multi-layer tubular 300 including a plurality of segments 340. In this example, the segments 340 are illustrated axially along the multi-layer tubular 300. The plurality of segments 340 may include a first segment 340A proximate a first connection 342, a second segment 340B proximate a second connection 344, and a third segment 340C between the first segment 340A and the second segment 340B. In at least one embodiment, the coagulant material (e.g., the flow restrictive material 310) may be positioned within the first segment 340A and the second segment 340B and not within the third segment 340C. For example, there may be a greater likelihood of leaks at the first and second segments 340A, 340B due to the first and second connections 342, 344, which may be identified as likely leak points. As a result, the multi-layer tubular 300 may reduce costs and/or weight by not including the flow restrictive material 310 in each segment 340.

FIG. 3E illustrates an example schematic and front cross-sectional view of an embodiment of the multi-layer tubular 300 and a leak detection system 350. In at least one embodiment, the leak detection system 350 may be a part of the cooling fluid system 222 and may further be used to receive a signal generated by one or more detection systems 352 associated with the multi-layer tubular 300. For example, the one or more detection systems 352 may generate a signal responsive to detecting one or more leak paths 354 associated with the first and second openings 316 and 318. For example, an inner leak flow path 354A may be associated with the first opening 316 and an outer leak flow path 354B may be associated with the second opening 318. For example, the cooling fluid 314 may enter the first opening 316 and interact with the flow restrictive material 310, which may cause one or more clogs 356, for example if the flow restrictive material 310 caused the cooling fluid 314 to coagulate and form the clog 356 at the second annular layer 306. The detection system 352 may include components such as moisture sensors, visual detection systems (e.g., cameras), and/or combinations thereof.

Accordingly, one or more embodiments of the present disclosure are directed toward the multi-layer tubular 300 that may include one or more materials (e.g., the flow restrictive material 310) that may be used to turn a fluid, such as the cooling fluid 314, into a hydrophobic fluid and/or to absorb the cooling fluid 314. As a nonlimiting example, the multi-layer tubular 300 may include at least the first annular layer 302 and the second annular layer 306 radially separated by the annular space 312. The annular space 312 may be filled, at least partially, with the flow restrictive material 310 to cause a liquid, such as the cooling fluid 314, that enters the annular space 312, through at least one of the inner leak flow path 354A formed in the first annular layer 302 or the outer leak flow path 354B formed in the second annular layer 306, to become hydrophobic or to absorb at least a portion of the liquid.

In one or more embodiments, the multi-layer tubular 300 forms a portion of a liquid cooling loop 360 associated with a server product to direct the cooling fluid 314, for example from a fluid supply 362 of the cooling fluid system 222, flowing through the flow bore 304 of the multi-layer tubular 300, toward heat producing units 364 to absorb and remove heat from the heat producing units 364. In at least one embodiment, the flow restrictive material 310 may be selected based, at least in part, on one or more thermal properties.

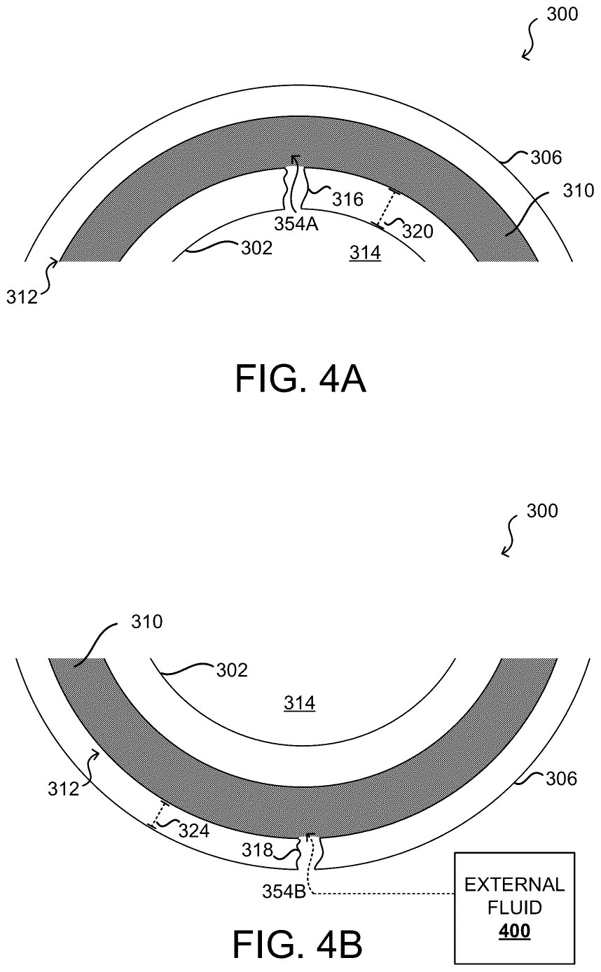

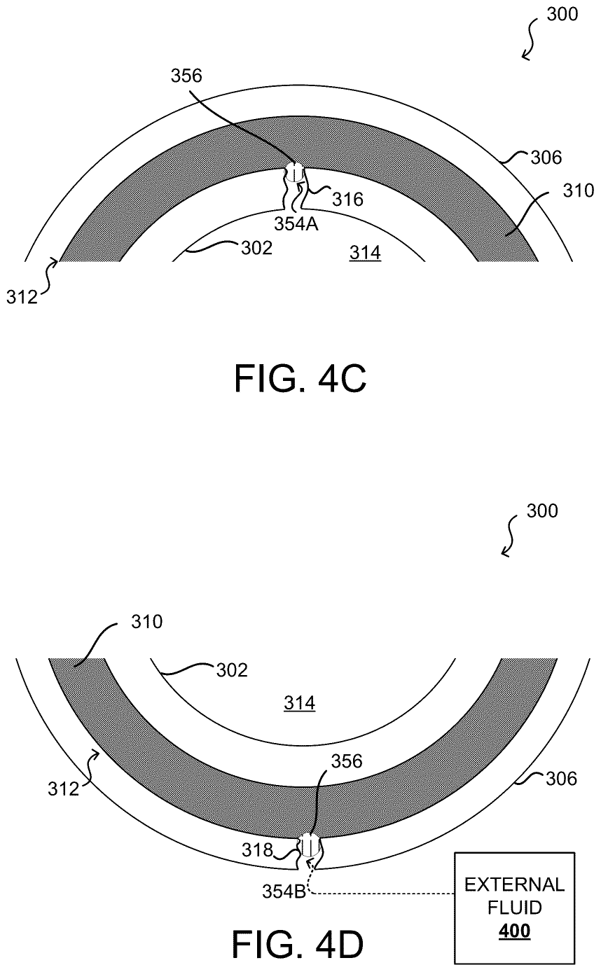

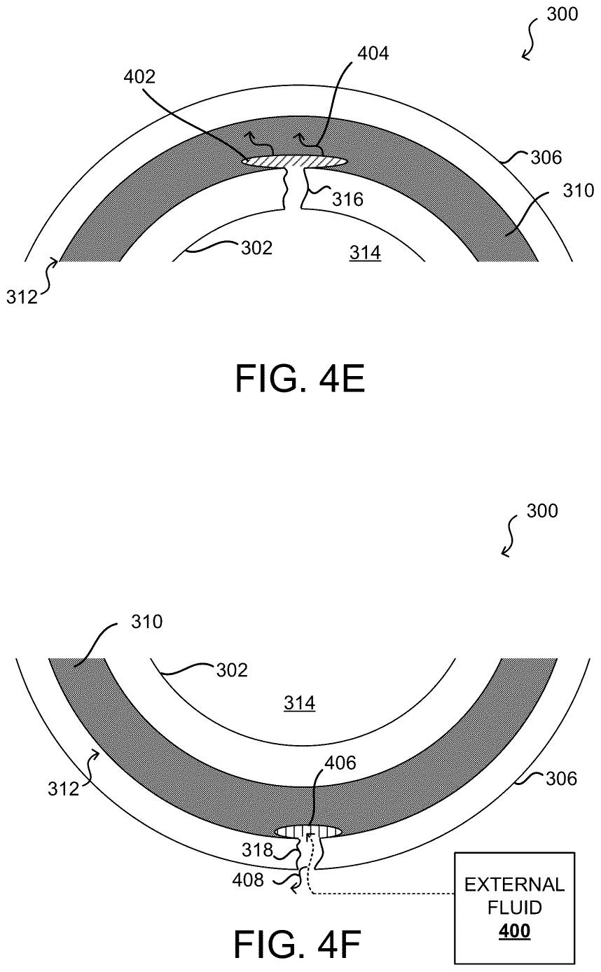

FIG. 4A illustrates a sectional front cross-sectional view of an embodiment of the multi-layer tubular 300 illustrating the inner leak flow path 354A extending through the first annular layer 302. In this example, the first opening 316 is shown to extend through the first radial thickness 320 of the first annular layer 302, thereby providing a passage through the first annular layer 302 for the cooling fluid 314 to flow toward the annular space 312. In this example, the flow restrictive material 310 is arranged within the annular space 312 such that the cooling fluid 314 contacts the flow restrictive material 310 as the cooling fluid 314 flows through the first opening 316 along the inner leak flow path 354A. As discussed herein, one or more embodiments of the present disclosure may particularly select the flow restrictive material 310 to block the flow along the inner leak flow path 354A.

FIG. 4B illustrates a sectional front cross-sectional view of an embodiment of the multi-layer tubular 300 illustrating the outer leak flow path 354B extending through the second annular layer 306. In this example, the second opening 318 is shown to extend through the second radial thickness 324 of the second annular layer 306. For example, an external force may damage the multi-layer tubular 300, thereby providing a passage through the second annular layer 306 for one or more external fluids 400 to flow toward the annular space 312. The external fluid 400 may include fluids such as condensation, spills or leaks from other equipment, or combinations thereof. In this example, the flow restrictive material 310 is arranged within the annular space 312 such that the external fluid 400 contacts the flow restrictive material 310 as the external fluid flows through the second opening 318 along the outer leak flow path 354B. As discussed herein, one or more embodiments of the present disclosure may particularly select the flow restrictive material 310 to block the flow along the outer leak flow path 354B.

FIG. 4C illustrates a sectional front cross-sectional view of an embodiment of the multi-layer tubular 300 illustrating the clog 356 formed along the inner leak flow path 354A. As discussed herein, as the cooling fluid 314 travels along the inner leak flow path 354A through the first opening 316, systems and methods may select the flow restrictive material 310 to be a coagulant that, upon contacting the cooling fluid 314, the clog 356 is formed to plug or otherwise block further flow along the inner leak flow path 354A. In this manner, the leak associated with the first opening 316 may be addressed, at least temporarily, to enable operations to continue. As discussed herein, one or more detection systems and may also be associated with the clog 356 to identify the clog 356 and provide an alert to schedule the multi-layer tubular 300 for inspection or replacement.

FIG. 4D illustrates a sectional front cross-sectional view of an embodiment of the multi-layer tubular 300 illustrating the clog 356 formed along the outer leak flow path 354B. In at least one embodiment, as the external fluid 400 attempts to ingress the multi-layer tubular 300 along the outer leak flow path 354B through the second opening 318, systems and methods may select the flow restrictive material 310 to be a coagulant that, upon contacting the external fluid 400, the clog 356 is formed to plug or otherwise block further flow along the outer leak flow path 354B. In this manner, the leak associated with the second opening 318 may be addressed, at least temporarily, to enable operations to continue. As discussed herein, one or more detection systems and may also be associated with the clog 356 to identify the clog 356 and provide an alert to schedule the multi-layer tubular 300 for inspection or replacement.

FIG. 4E illustrates a sectional front cross-sectional view of an embodiment of the multi-layer tubular 300 illustrating an absorbent region 402 within the flow restrictive material 310 responsive to contact with the cooling fluid 314. In this example, the absorbent region 402 may receive the cooling fluid 314 from the first opening 316. The flow restrictive material 310 may be a material such as microfiber materials, polymers, and/or natural fibers, such as bamboo. In at least one embodiment the flow restrictive material 310 may be configured to wick 404 away the cooling fluid 314 throughout the flow restrictive material 310. As discussed herein, one or more detection systems and may also be associated with the flow restrictive material 310 and/or the absorbent region 402 to identify the ingress of the cooling fluid 314.

FIG. 4F illustrates a sectional front cross-sectional view of an embodiment of the multi-layer tubular 300 illustrating a hydrophobic region 406 within the flow restrictive material 310 responsive to contact with the external fluid 400. In this example, the hydrophobic region 406 may receive the external fluid 400 from the second opening 318. In at least one embodiment the flow restrictive material 310 may be configured to block further ingress of the external fluid 400 by repelling 408 the external fluid 400. As discussed herein, one or more detection systems and may also be associated with the flow restrictive material 310 and/or the hydrophobic region 406 to identify the ingress of the external fluid 400.

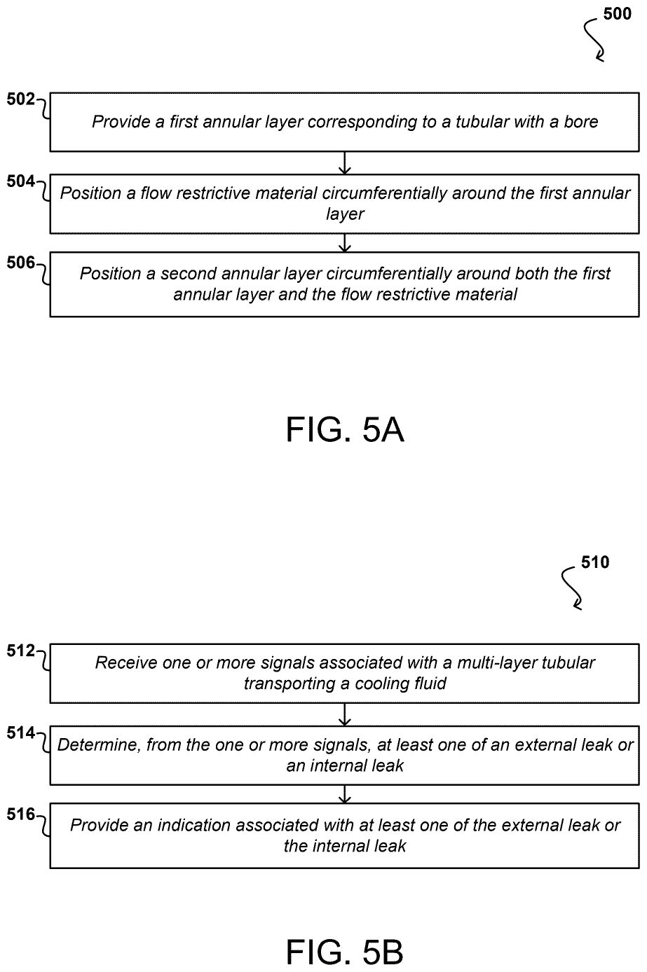

FIG. 5A illustrates an example process 500 for forming a multi-layer tubular that may be used with one or more embodiments of the present disclosure. It should be appreciated that steps for the method may be performed in any order, or in parallel, unless otherwise specifically stated. Moreover, the method may include more or fewer steps.

In this example, a first annular layer corresponding to a tubular with a bore is provided 502. As discussed herein, the tubular may be a hose or flow connection component, among other options, and the bore may be a flow bore to transport a cooling fluid. In at least one embodiment, the first annular layer may be formed from a material to facilitate heat transfer and/or to resist one or more chemical properties of the cooling fluid. A flow restrictive material may be positioned around the first annular layer 504. For example, the flow restrictive material may be wrapped about the first annular layer. In certain embodiments, the flow restrictive material may be layered over the first annular layer. Additionally, multiple types of flow restrictive material may positioned around the first annular layer. In certain embodiments, there may be a gap between the flow restrictive material and the first annular layer. In one or more embodiments, the flow restrictive material may be compressed or otherwise positioned against the first annular layer. A second annular layer may be positioned around both the first annular layer and the flow restrictive material 506. In various embodiments, the flow restrictive material may be sandwiched between or otherwise contained with an annular space between the first annular layer and the second annular layer. In this manner, a multi-layer tubular may be formed.

FIG. 5B illustrates an example process 510 for a leak detection system using a multi-layer tubular that may be used with one or more embodiments of the present disclosure. This one example, one or more signals associated with a multi-layer tubular transporting a cooling fluid may be received 512. The one or more signals may be indicative of a breach or opening formed in one or more layers of the multi-layer tubular. In at least one embodiment, the one or more signals may be used to determine a location of the leak 514. For example, it may be determined whether the one or more signals corresponds to at least one of an external leak or an internal leak. An indication may then be provided associated with the determined internal or external leak 516.

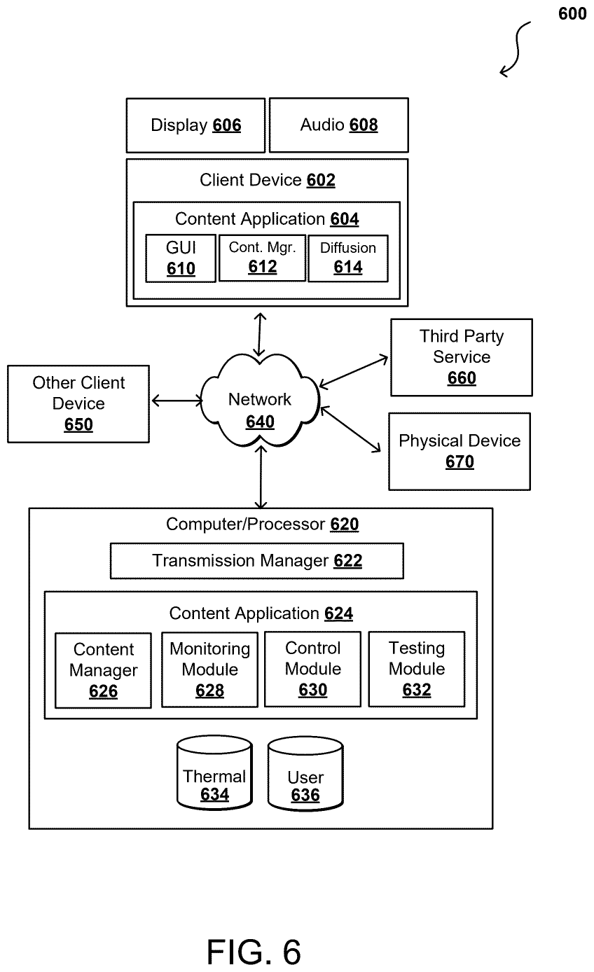

FIG. 6 illustrates an example network configuration 600 of components that can be used to implement aspects of various embodiments, such as to provide, generate, modify, encode, process, fuse, and/or transmit generated image data, calculated measurements, or other such content. In at least one embodiment, a client device 602 can generate or receive data for a session using components of a content application 604 on the client device 602 and data stored locally on that client device. In at least one embodiment, a content application 624 executing on a computer or processor 620 (e.g., a cloud server or control system) may initiate a session associated with at least one client device 602 (e.g., a vehicle or robot), as may use a session manager and user data stored in a user database 636, and can cause content such as liquid coolant or server thermal data to be selected and/or retrieved from a repository 634 to be used by a testing module 632 to calculate one or more performance metrics for a monitoring module 628, which can provide flow data or thermal data to a control module 630 to control a flow or temperature, in an environment where the data is to be used to determine appropriate operation. A content manager 626 may work with at these various modules to perform testing and analysis, and potentially instruct any actions to be taken in response to a performance metric failing to satisfy an operational requirements. At least a portion of this data or instructional content can be transmitted to the client device 602 and/or a physical device 670 using an appropriate transmission manager 622 to send by download, streaming, or another such transmission channel. An encoder may be used to encode and/or compress at least some of this data before transmitting to the client device 602. In at least one embodiment, the client device 602 receiving such content can provide this content to a corresponding content application 604, which may also or alternatively include a graphical user interface 610, a flow monitor module 612, and a control module 614 for use in providing, synthesizing, rendering, compositing, modifying, or using content for presentation, navigation, control, (or other purposes) on or by the client device 602, such as may be transmitted to the physical device 670. In some embodiments, the computer/processor 620 and client device 602 may be able to communicate directly without needing to transmit data over a network 640, in order to avoid issues with latency and availability, etc. A decoder may also be used to decode data received over the network 640 for presentation via client device 602, such as imaging content or performance metrics through a display device 606 and audio, such as corresponding sounds or synthesized speech, through at least one audio playback device 608, such as speakers or headphones. In at least one embodiment, at least some of this content may already be stored on, rendered on, or accessible to client device 602 such that transmission over a network 640 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 620, or user database 636, to the client device 602. In at least one embodiment, at least a portion of this content can be obtained, enhanced, and/or streamed from another source, such as a third party service 660 or other client device 650, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit), (DPUs), (QPUs), or a plurality of parallel processing units (PPUs).

In this example, these client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, which sits on a network edge and is outside at least one security layer associated with the cloud provider environment. In this way, latency can be reduced by enabling the client devices to interact with servers that are in closer proximity, while also improving security of resources in the cloud provider environment.

In at least one embodiment, such a system can be used for performing graphical rendering operations. In other embodiments, such a system can be used for other purposes, such as for providing image or video content to test or validate autonomous machine applications, or for performing deep learning operations. In at least one embodiment, such a system can be implemented using an edge device, or may incorporate one or more Virtual Machines (VMs). In at least one embodiment, such a system can be implemented at least partially in a data center or at least partially using cloud computing resources.

### Data Center

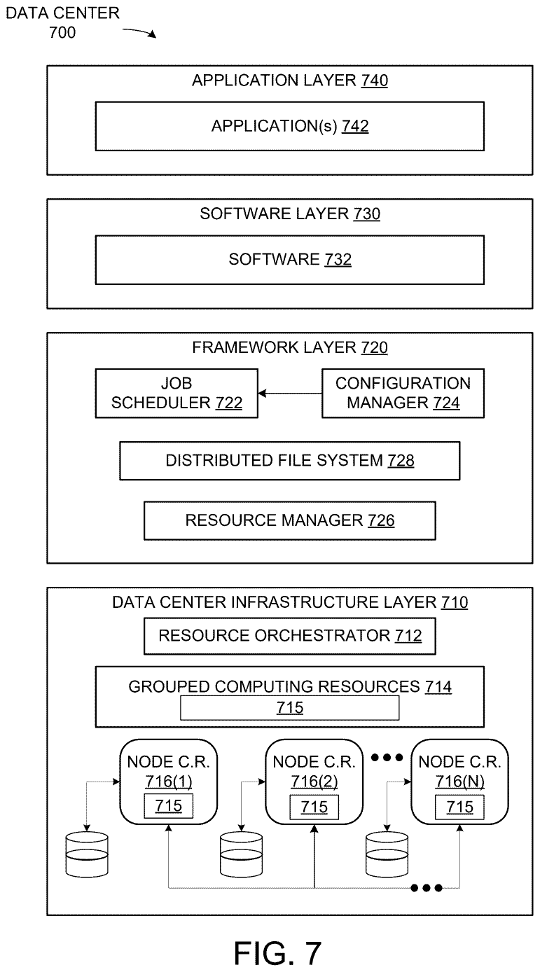

FIG. 7 illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may use distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 714 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underused and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, DPUs, QPUs, a network interface controller (NIC), FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. In at least one embodiment, inference and/or training logic 715 may be used in system FIG. 7 for inferencing or predicting operations based, at least in part, on weight parameters calculated using neural network training operations, neural network functions and/or architectures, or neural network use cases described herein.

Such components can be used in data centers that use liquid cooling systems.

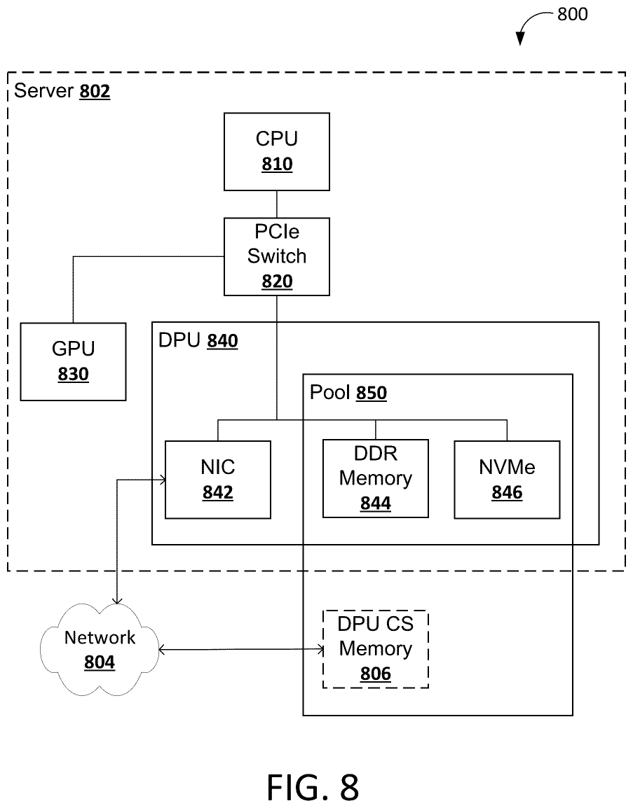

FIG. 8 illustrates an example computing environment 800 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 800 may include a server 802 which may be used to perform HPC workloads, such as AI training or machine learning model training. In an embodiment, the server 802 may be an application instance or a compute node. The server 802 may include a CPU 810 associated with a switch 820, such as a peripheral component interconnect express (PCIe) switch, which may control at least some data transmission over communication paths interconnecting various components. In an embodiment, the CPU 810 may include a root complex processor.

The PCIe switch 820 may also be associated with a GPU 830 and a DPU 840, and may transmit data between at least some of the CPU 810, the GPU 830, the DPU 840, and other components. In an embodiment, the PCIe switch 820 may be associated with more than one GPU or more than one DPU. In another embodiment, the PCIe switch 820 may be located within the DPU 840. The PCIe switch 820 may manage the transfer of at least some data between the CPU 810, the GPU 830, and the DPU 840. In another embodiment, the number of GPUs associated with the PCIe switch 820 may be equal to the number of DPUs associated with the PCIe switch 820. In at least one embodiment, the server 802 may include, without limitation, any number of the CPUs 810, the PCIe switches 820, the GPUs 830, and/or the DPUs 840, in any combination. For example, in at least one embodiment, server 802 could include eight, sixteen, thirty-two, and/or more GPUs 830. In at least one embodiment, communication paths interconnecting various components, including but not limited to the CPU 810, the PCIe switch 820, the GPU 830, and the DPU 840, in FIG. 8 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 840 may include a network interface card (NIC) 842, a DDR memory 844, and a non-volatile memory express (NVMe) device 846. The NIC 842 may be able to interface with a network 804, which may also interface with additional NVMe devices available to the DPU 840, such as over fabric. In an embodiment, the DPU 840 may not include the NVMe device 846. In another embodiment, the NVMe device 846 may be located on the server 802 and not on the DPU 840. In yet another embodiment, the computing environment 800 may include more than one of the NVMe device 846, such as a first NVMe device in the DPU 840 and a second first NVMe device on the server 802 an associated directly with the PCIe switch 820. In an embodiment, the DPU 840 may not include the DDR memory 844 and may include a computational storage services (CSS) in place of, or in addition to, the DDR memory 844. For example, computing environment 800 may include DPU computational storage (CS) memory 806 available to the DPU 840 as part of the CSS. The network 804 may be able to interface with the DPU CS memory 806 through the NIC 842, according to any suitable interface protocol, such as remote direct memory access (RDMA) over Ethernet, InfiniBand, Fiber Channel, etc.

The total memory of the computing environment 800 available for data storage may be expanded through the use of the DPU 840 on nodes of the system. The DPU 840 may have access to a pool 850 of memory already available to the server 802, such as double data rate (DDR) memory, on-board NVMe devices, NVMe devices over fabric, and CS. The pool 850 of memory may include at least one of the DDR memory 844, NVMe 846, and the DPU CS memory 806. The DPU 840 may also be able to access the available memory of other DPUs as part of the pool 850, and other DPUs may be able to access the available memory of DPU 840, such as the pool 850. This available memory can be accessed and utilized for data storage, without the addition of compute resources, such as compute nodes, which would be required using other solutions. The available pool 850 accessible to the DPU 840 may be provisioned for the server 802 to expand the total memory available for data storage, such as to reduce the data storage load on the CPU 810 or the GPU 830, which can instead increase the utilization of their memory for processing. For example, during training of an AI, the model states, residual states, activation functions, and checkpoints can be stored, or offloaded, on the pool 850 accessible to the DPU 840.

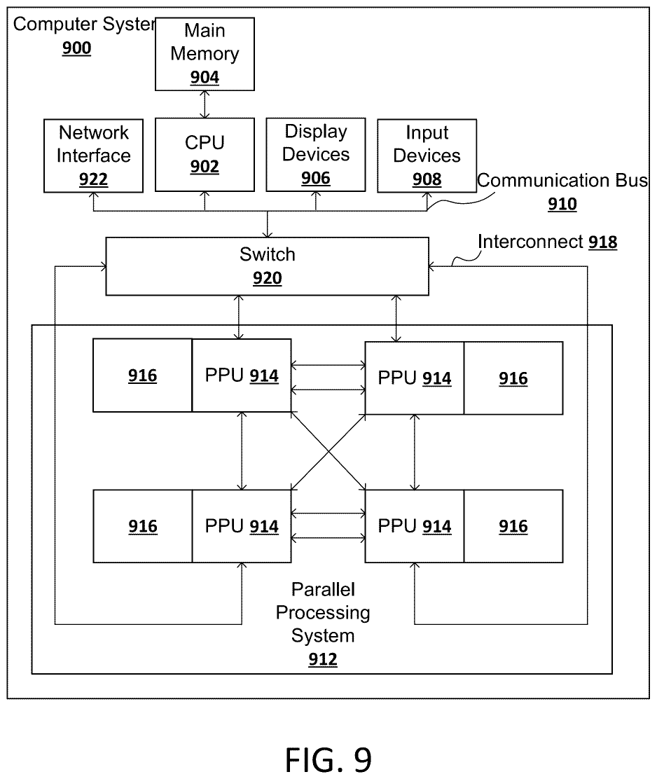

FIG. 9 illustrates a computer system 900, according to at least one embodiment. In at least one embodiment, computer system 900 is configured to implement various processes and methods described throughout this disclosure.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 900, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable system 900 to perform various functions in accordance with at least one embodiment. memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as_syncthreads( ), wherein all threads in a block (e.g., executed across multiple PPUs 914) to reach a certain point of execution of code before proceeding.

Such components can be used in data centers that use liquid cooling systems.

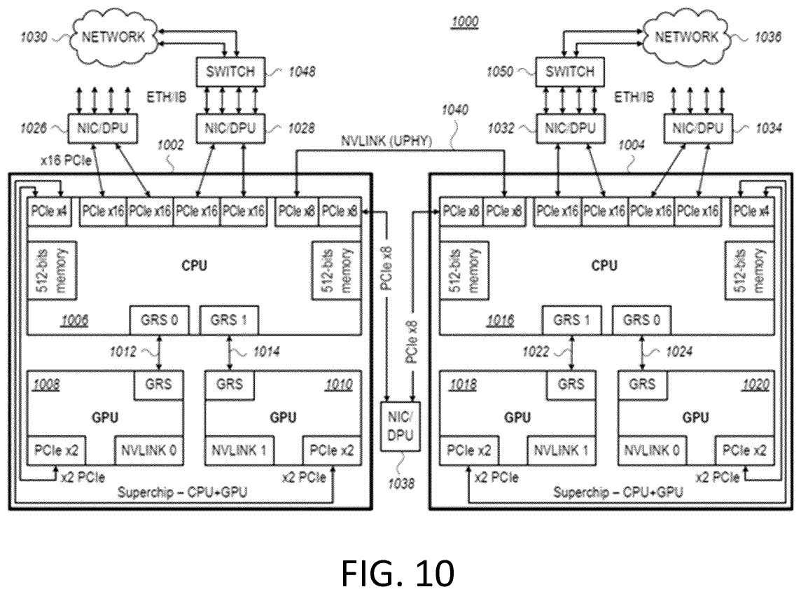

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g., multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 10, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communicate with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs.

In various embodiments, any of the network devices of system 1000, e.g., any of NICs/DPUs 1026, 1028, 1032, 1034 and 1038, and/or any of switches 1048 and 1050, may use ILI packets in accordance with the techniques described herein. Such components can be used in data centers that use liquid cooling systems.

Various embodiments can be described by the following clauses:
1. A cooling fluid transport tubular, comprising:
   a first layer forming a flow bore;
   a second layer positioned radially outward from and coaxial with the first layer; and
   a flow restrictive material positioned within an annular space between a first annular layer and a second annular layer, to restrict flow of a cooling fluid, within the flow bore, responsive to at least one of a first opening in the first annular layer or a second opening in the second annular layer.
   2. The cooling fluid transport tubular of clause 1, wherein the flow restrictive material is a hydrophobic material is at least one of an acrylic, an epoxy, a polyethylene, a polystyrene, a polyvinylchloride, a polytetrafluorethylene, a polydimethylsiloxane, a polyester, or a polyurethane.
   3. The cooling fluid transport tubular of clause 1, wherein the flow restrictive material is a coagulant that, when mixed with the cooling fluid, causes at least a portion of the cooling fluid to become hydrophobic.
   4. The cooling fluid transport tubular of clause 1, wherein the flow restrictive material is a coagulant that, when mixed with the cooling fluid, causes a mixture of the cooling fluid and the flow restrictive material to clog the second opening.
   5. The cooling fluid transport tubular of clause 1, wherein the first annular layer is formed from a first material and the second annular layer is formed from a second material.
   6. The cooling fluid transport tubular of clause 5, wherein the first annular layer is a flexible polymer and the second annular layer is a puncture resistant material.
   7. The cooling fluid transport tubular of clause 6, wherein the puncture resistant material comprises at least one of a carbon fiber weave, an acrylonitrile butadiene styrene, or a metallic braiding.
   8. A system, comprising:
   an inner layer proximate a flow bore for a cooling fluid;
   an annular space around the inner layer, separated from the flow bore by the inner layer; and
   an outer layer proximate the annular space and separated from the flow bore by both the annular space and the inner layer;
   wherein the annular space includes a coagulant material that, upon contacting the cooling fluid responsive to an inner leak path in the inner layer, causes the cooling fluid to become a hydrophobic material, and upon becoming a hydrophobic material, clogs an outer leak path in the outer layer.
   9. The system of clause 8, wherein the inner layer is formed from a first material and the outer layer is formed from a second material.
   10. The system of clause 9, wherein the inner layer is a flexible polymer and the outer layer is a puncture resistant material.
   11. The system of clause 10, wherein the puncture resistant material comprises at least one of a carbon fiber weave, acrylonitrile butadiene styrene, or a metallic braiding.
   12. The system of clause 8, wherein the inner layer, the annular space, and the outer layer form a tubular, and a length of the tubular is segmented into a plurality of segments, comprising:
   a first segment proximate a first connection;
   a second segment proximate a second connection; and
   a third segment between the first segment and the second segment, wherein the coagulant material is positioned within the first segment and the second segment and not within the third segment.
   13. The system of clause 8, wherein the annular space is segmented into a plurality of segments, comprising:
   a first segment that includes the coagulant material;
   a second segment that includes the coagulant material; and
   a third segment that does not include the coagulant material.
   14. The system of clause 8, further comprising:
   a leak detection system generating a signal responsive to detecting at least one of the inner leak path or the outer leak path based, at least in part, on the clog at the outer layer.
   15. The system of clause 8, wherein a first radial thickness of the annular space is greater than a second radial thickness of the inner layer and a third radial thickness of the outer layer.
   16. The system of clause 8, wherein a first radial thickness of the annular space is less than at least one of a second radial thickness of the inner layer or a second radial thickness of the outer layer.
   17. The system of clause 8, wherein the coagulant material is at least one of aluminum sulfate, aluminum chloride, sodium aluminate, ferric sulfate, ferrous sulfate, ferric chloride, or ferric chloride sulfate.
   18. A multi-layer cooling fluid hose comprising at least a first layer and a second layer radially separated by an annular space, the annular space being filled, at least partially, within a flow-restrictive material to cause a liquid that enters the annular space, through at least one of a first leak path formed in the first layer or a second leak path formed in the second layer, to become hydrophobic or to absorb at least a portion of the liquid.
   19. The multi-layer cooling fluid hose of clause 18, wherein the multi-layer cooling fluid hose forms a portion of a liquid cooling loop associated with a server product to direct a cooling fluid, flowing through a bore of the multi-layer cooling fluid hose, toward heat producing units to absorb and remove heat from the heat producing units.
   20. The multi-layer cooling fluid hose of clause 18, wherein the flow-restrictive material is selected based, at least in part, on one or more thermal properties.
   21. A data center comprising:
   one or more device racks; and
one or more multi-layer cooling fluid hoses for transporting a cooling fluid within the device racks, the multi-layer cooling fluid hoses comprising at least a first layer and a second layer radially separated by an annular space, the annular space being filled, at least partially, within a flow-restrictive material to cause a liquid that enters the annular space, through at least one of a first leak path formed in the first layer or a second leak path formed in the second layer, to become hydrophobic or to absorb at least a portion of the liquid.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors-for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU, DPU, QPU, or a plurality of parallel processing units (PPUs). A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A cooling fluid transport tubular, comprising:
a first layer forming a flow bore;
a second layer positioned radially outward from and coaxial with the first layer; and
a flow restrictive material positioned within an annular space between a first annular layer and a second annular layer, to restrict flow of a cooling fluid, within the flow bore, responsive to at least one of a first opening in the first annular layer or a second opening in the second annular layer.

2. The cooling fluid transport tubular of claim 1, wherein the flow restrictive material is a hydrophobic material is at least one of an acrylic, an epoxy, a polyethylene, a polystyrene, a polyvinylchloride, a polytetrafluorethylene, a polydimethylsiloxane, a polyester, or a polyurethane.

3. The cooling fluid transport tubular of claim 1, wherein the flow restrictive material is a coagulant that, when mixed with the cooling fluid, causes at least a portion of the cooling fluid to become hydrophobic.

4. The cooling fluid transport tubular of claim 1, wherein the flow restrictive material is a coagulant that, when mixed with the cooling fluid, causes a mixture of the cooling fluid and the flow restrictive material to clog the second opening.

5. The cooling fluid transport tubular of claim 1, wherein the first annular layer is formed from a first material and the second annular layer is formed from a second material.

6. The cooling fluid transport tubular of claim 5, wherein the first annular layer is a flexible polymer and the second annular layer is a puncture resistant material.

7. The cooling fluid transport tubular of claim 6, wherein the puncture resistant material comprises at least one of a carbon fiber weave, an acrylonitrile butadiene styrene, or a metallic braiding.

8. A system, comprising:
an inner layer proximate a flow bore for a cooling fluid;
an annular space around the inner layer, separated from the flow bore by the inner layer; and
an outer layer proximate the annular space and separated from the flow bore by both the annular space and the inner layer;
wherein the annular space includes a coagulant material that, upon contacting the cooling fluid responsive to an inner leak path in the inner layer, causes the cooling fluid to become a hydrophobic material, and upon becoming a hydrophobic material, clogs an outer leak path in the outer layer.

9. The system of claim 8, wherein the inner layer is formed from a first material and the outer layer is formed from a second material.

10. The system of claim 9, wherein the inner layer is a flexible polymer and the outer layer is a puncture resistant material.

11. The system of claim 10, wherein the puncture resistant material comprises at least one of a carbon fiber weave, acrylonitrile butadiene styrene, or a metallic braiding.

12. The system of claim 8, wherein the inner layer, the annular space, and the outer layer form a tubular, and a length of the tubular is segmented into a plurality of segments, comprising:
a first segment proximate a first connection;
a second segment proximate a second connection; and
a third segment between the first segment and the second segment, wherein the coagulant material is positioned within the first segment and the second segment and not within the third segment.

13. The system of claim 8, wherein the annular space is segmented into a plurality of segments, comprising:
a first segment that includes the coagulant material;
a second segment that includes the coagulant material; and
a third segment that does not include the coagulant material.

14. The system of claim 8, further comprising:
a leak detection system generating a signal responsive to detecting at least one of the inner leak path or the outer leak path based, at least in part, on the clog at the outer layer.

15. The system of claim 8, wherein a first radial thickness of the annular space is greater than a second radial thickness of the inner layer and a third radial thickness of the outer layer.

16. The system of claim 8, wherein a first radial thickness of the annular space is less than at least one of a second radial thickness of the inner layer or a second radial thickness of the outer layer.

17. The system of claim 8, wherein the coagulant material is at least one of aluminum sulfate, aluminum chloride, sodium aluminate, ferric sulfate, ferrous sulfate, ferric chloride, or ferric chloride sulfate.

18. A multi-layer cooling fluid hose comprising at least a first layer and a second layer radially separated by an annular space, the annular space being filled, at least partially, within a flow-restrictive material to cause a liquid that enters the annular space, through at least one of a first leak path formed in the first layer or a second leak path formed in the second layer, to become hydrophobic or to absorb at least a portion of the liquid.

19. The multi-layer cooling fluid hose of claim 18, wherein the multi-layer cooling fluid hose forms a portion of a liquid cooling loop associated with a server product to direct a cooling fluid, flowing through a bore of the multi-layer cooling fluid hose, toward heat producing units to absorb and remove heat from the heat producing units.

20. The multi-layer cooling fluid hose of claim 18, wherein the flow-restrictive material is selected based, at least in part, on one or more thermal properties.

21. A data center comprising:
one or more device racks; and
one or more multi-layer cooling fluid hoses for transporting a cooling fluid within the device racks, the multi-layer cooling fluid hoses comprising at least a first layer and a second layer radially separated by an annular space, the annular space being filled, at least partially, within a flow-restrictive material to cause a liquid that enters the annular space, through at least one of a first leak path formed in the first layer or a second leak path formed in the second layer, to become hydrophobic or to absorb at least a portion of the liquid.
